(19) United States
(12) Patent Application Publication
(10) Pub. No.: US 2012/0300395 A1
(43) Pub. Date: Nov. 29, 2012

(54) TABLE PC BRACKET

(75) Inventor: Yi-Chang Su, Taipei City (TW)

(73) Assignee: EVERCASE TECHNOLOGY INC., Taipei City (TW)

(21) Appl. No.: 13/168,208

(22) Filed: Jun. 24, 2011

(30) Foreign Application Priority Data
May 25, 2011 (CN) 201120176462.0

(51) Int. Cl. H05K 7/18

(52) U.S. Cl. 361/679.55

(57) ABSTRACT

The present invention relates to a support bracket for tablet personal computer (tablet PC), including a support board and a support footing. The support board consists of a backboard, a prop-up member and a plurality of engaging members to support the back of tablet PC. Each engaging member contains a neck and a head. The support footing contains a first supporting plate and a second supporting plate, which form a bend and each having an engaging hole. Each engaging hole has a big hole that enables the head of any aforementioned engaging member to pass through and a small hole that could engage the corresponding neck. When any one of the aforementioned engaging holes engages any one of the aforementioned engaging members through its small hole, while the supporting plate of the other engaging hole is not pressed close to the prop-up member, the tablet PC bracket could be braced on a desktop/ground surface through the supporting plate not pressed close to the prop-up member and the prop-up member.

### FIELD OF THE INVENTION

The present invention relates to a tablet personal computer (tablet PC) bracket, more particularly a tablet PC bracket that could change the ways of support.

### BACKGROUND

Along with technological advancement, tablet PC stresses the features of small size, light weight and ease of carriage. But as tablet PC is used in different environments, it might need to be held or mounted in different ways to render its use more convenient. Thus the demand for tablet PC bracket arises. Typical tablet PC bracket employs a flat base with all kinds of support elements installed thereon. Although the base comes in a variety of structure, such as in the form of a long plate or inverted V-shape, the base must be arranged on an even surface. Such bracket usually has problem staying firm and steady when the surface it stands on is unsteady or uneven.

### SUMMARY OF THE INVENTION

In light of the drawback of prior art, the present invention provides a tablet PC bracket that could change its way of support by changing how its parts are assembled.

The present invention discloses a tablet PC bracket, comprising a support board and a support footing. The support board consists of a backboard, a prop-up member and a plurality of engaging members. The backboard is used for supporting the back of the tablet PC. The prop-up member is arranged at the bottom of the front side of the backboard. Each engaging member consists of a neck and a head. One end of the neck is connected to back side of the backboard, while the other end of the neck is connected to the head. The support footing comprises a first supporting plate and a second supporting plate. The first supporting plate has a first engaging hole. The second supporting plate is connected to the first supporting plate in such a way that the support footing forms a bend, the second supporting plate having a second engaging hole. Both the first engaging hole and the second engaging hole contain a big hole that allows any head of the plurality of engaging members to pass through the support footing, and a small hole that could engage any neck of the plurality of engaging members. When the first supporting plate engages any one of the plurality of engaging members through the first engaging hole and the second supporting plate is not pressed close to the prop-up member, the tablet PC bracket could be braced on a desktop/ground surface through the second supporting plate and the prop-up member. When the second supporting plate engages any one of the plurality of engaging members through the second engaging hole and the first supporting plate is not pressed close to the prop-up member, the tablet PC bracket could be braced on a ground surface through the first supporting plate and the prop-up member.

Therefore, by changing the way of assembling the support board and the support footing, the present invention is able to change the angle of support and adapt to all kinds of application environment.

The objects, features and effects of the invention are described in detail below with embodiments in reference to the accompanying drawings.

### BRIEF DESCRIPTION OF THE DRAWINGS

FIG. 1 is front view of an embodiment of the invention;

FIG. 2 is a side view of a support board in FIG. 1;

FIG. 3 is a top view of a support board in FIG. 1;

FIG. 4 is a rear view of a support board in FIG. 1;

FIG. 5 is an exploded view of a support board installed with a rubber pad in an embodiment of the invention;

FIG. 6 is a perspective view of a support board in FIG. 5;

FIG. 7 is a perspective view of a support footing in an embodiment of the invention;

FIG. 8 is an exploded view of a tablet PC bracket in the first embodiment of the invention;

FIG. 9 is a rear perspective view of a tablet PC bracket in FIG. 8;

FIG. 10 is a side perspective view of a tablet PC bracket in FIG. 8;

FIG. 11 is a perspective view of a tablet PC bracket in a second embodiment of the invention;

FIG. 12 is a side view of a tablet PC bracket in folded state in an embodiment of the invention;

FIG. 13 is an exploded view of a tablet PC bracket in a third embodiment of the invention; and

FIG. 14 is a perspective view of a tablet PC bracket in FIG. 13.

### DETAILED DESCRIPTION OF THE INVENTION

The tablet PC bracket of the invention comprises mainly two large components—a support board and a support footing, and can achieve different support angles or space-saving storage by assembling the two components in different ways. To facilitate an understanding of the operating principles of tablet PC according to the invention, the sections below will first describe detailed structures of the support board and the support footing, followed by the methods of their assembly.

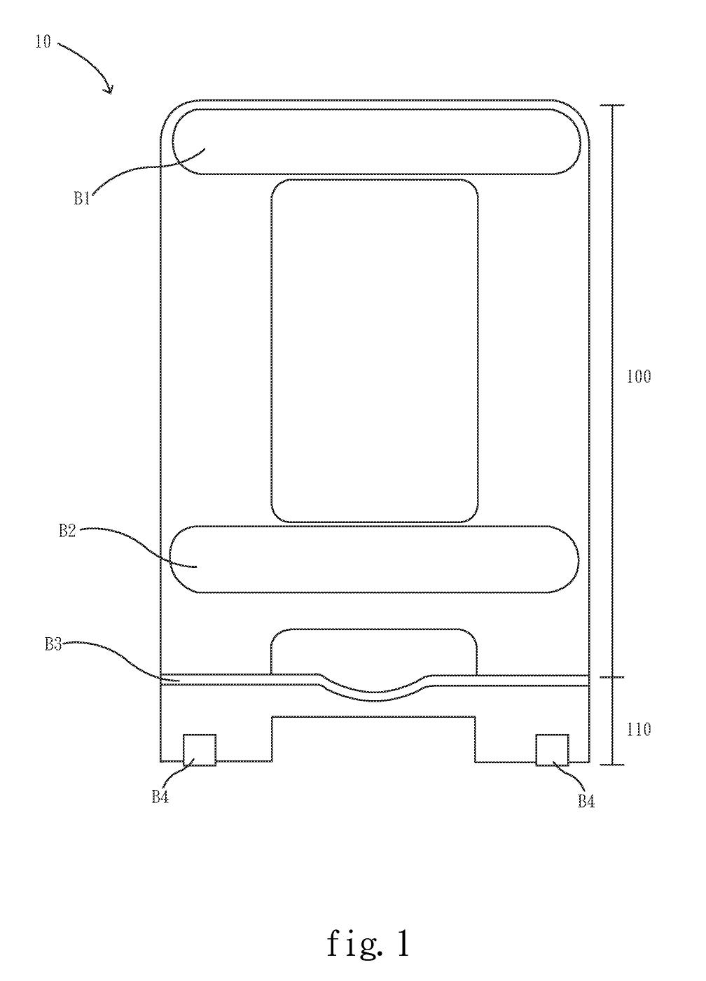

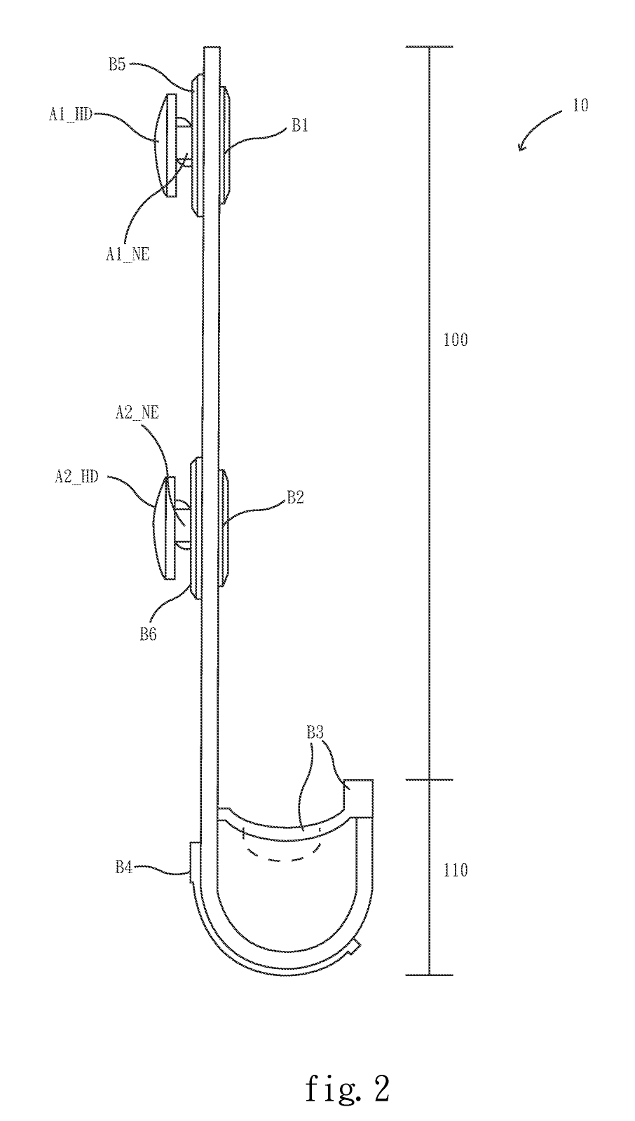

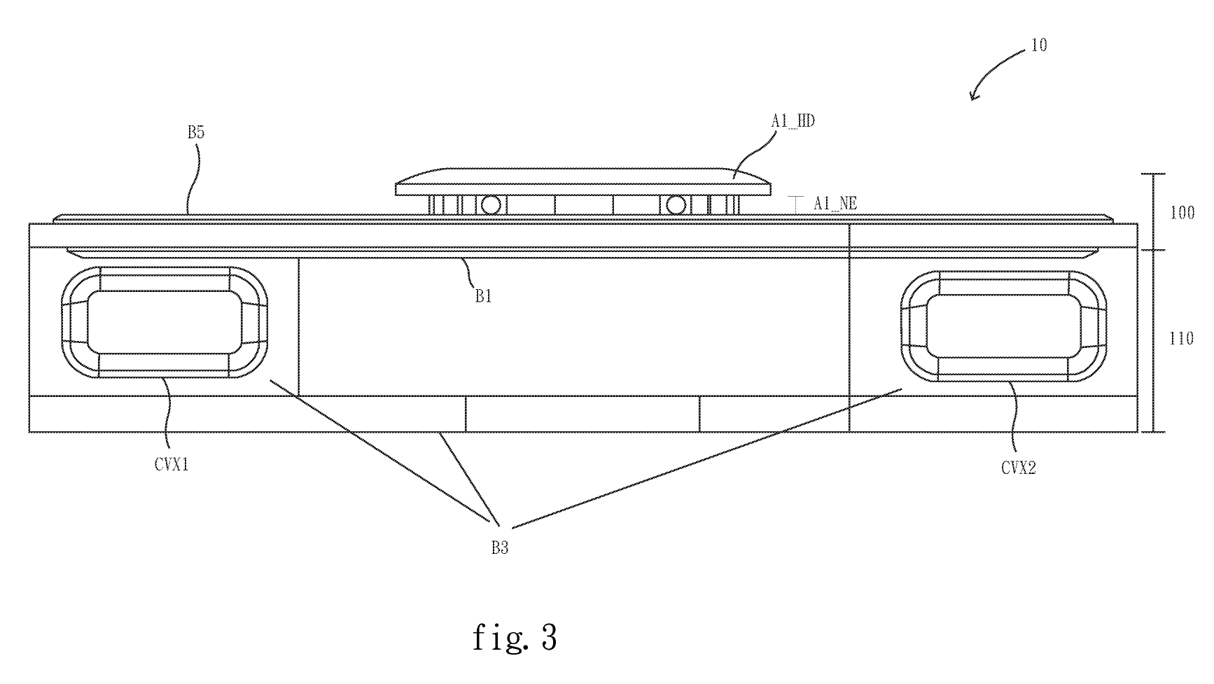

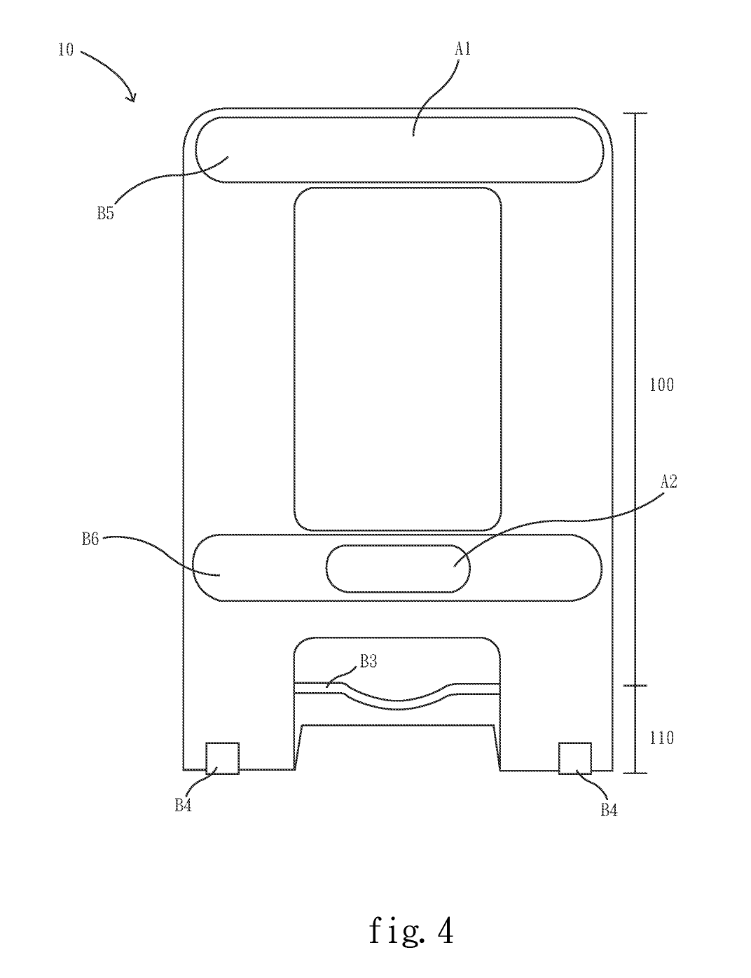

FIGS. 1-4 show respectively a front view, side view, top view and rear view of a support board 10 in an embodiment of the invention. The support board 10 consists mainly of a backboard 100, a prop-up member 110 and engaging members A1, A2. The front side of the backboard 100 is used for supporting the back of a tablet PC. The prop-up member 110 arranged at the bottom of the front side of the backboard 100 is used for supporting the bottom of a tablet PC when it is placed upright and for supporting the side of a tablet PC when it is placed horizontally. Engaging members A1, A2 are arranged respectively at the top and lower portion of the back side of the backboard 100 (as shown in FIG. 4). Engaging member A1 includes a neck A1_NE and a head A1_HD. Engaging member A2 includes a neck A2_NE and a head A₂—HD (as shown in FIG. 2). As shown in FIG. 3, the neck A1_NE is composed a main post in the middle and an auxiliary post on each side. A rolling ball type engaging element is disposed between the main post and each of the auxiliary posts. Such constructions should be familiar to people with common knowledge in the field and will not be elaborated here. Neck A2_NE and neck A1_NE have the same constructions.

The support board 10 also contains rubber pieces B1-B6 for reducing friction, of which, rubber pieces B1 and B2 could reduce the back friction of tablet PC, rubber piece B3 could reduce the bottom friction of tablet PC, rubber piece B4 could reduce the friction between support board 10 and desktop/ground surface, while rubber pieces B5 and B6 could reduce the friction generated when the support board 10 couples with the support footing.

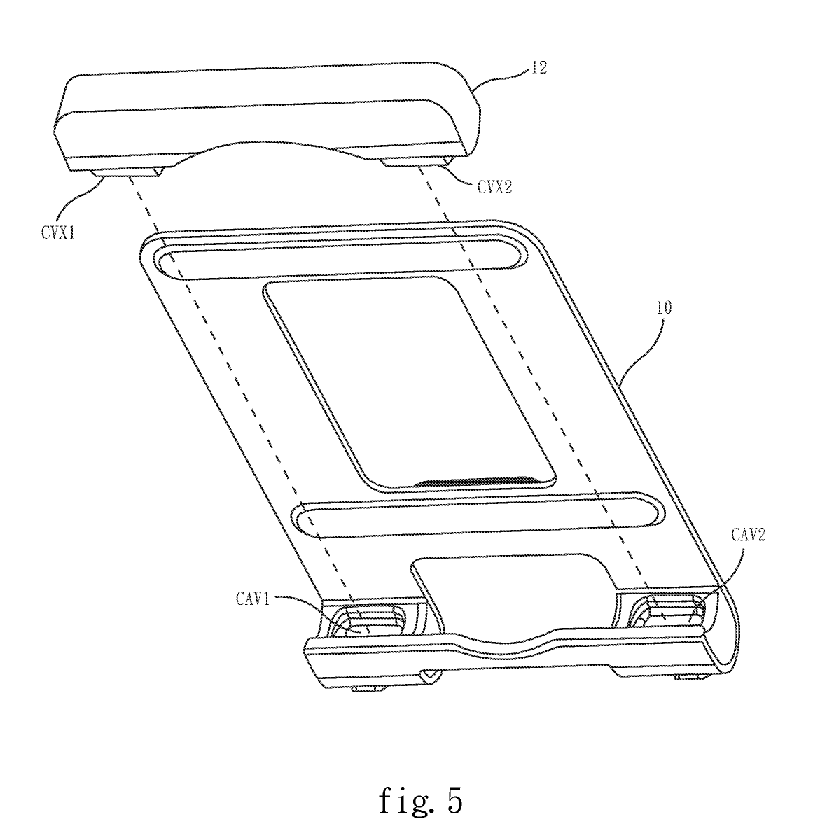

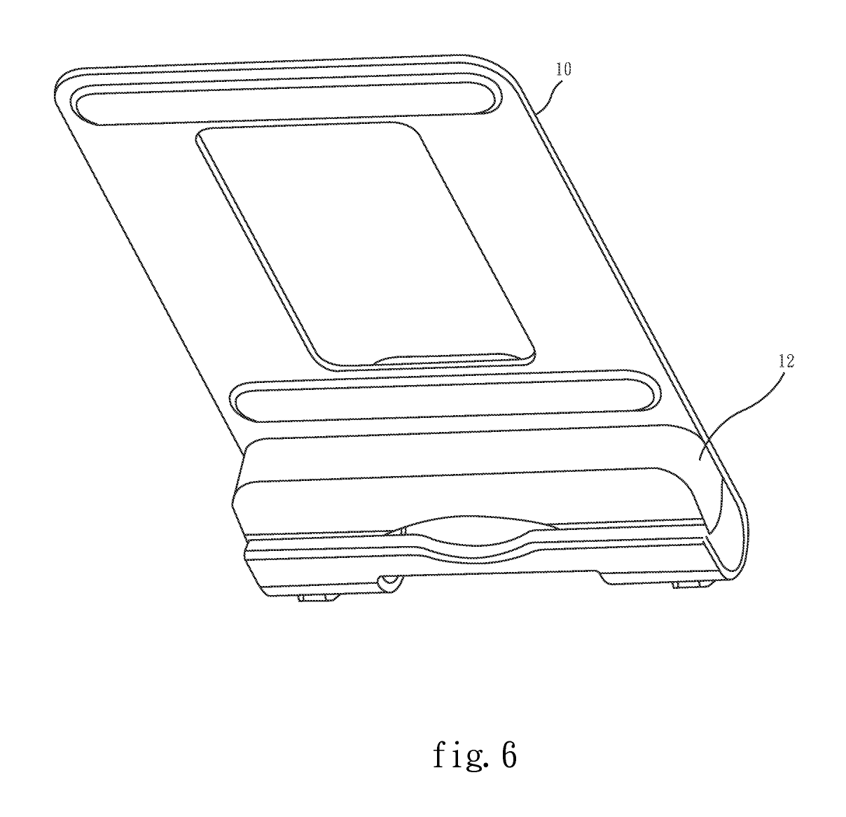

In addition, in FIG. 3, CVX1 and CVX2 are concavities formed on rubber piece B3 for coupling with the rubber pad so as to raise the prop-up member to support other small electronic devices, such as smartphone or mini notebook (e.g. Apple MacBook Air, Google Chromebook, ASUS Ecc Pc, Acer Aspire One). As shown in FIG. 5, concavities CVX1 and CVX2 of the support board 10 could be coupled respectively with the convexities CAV1 and CAV2 of a rubber pad 12 so that rubber pad 12 could be secured to the support board 10 as shown in FIG. 6.

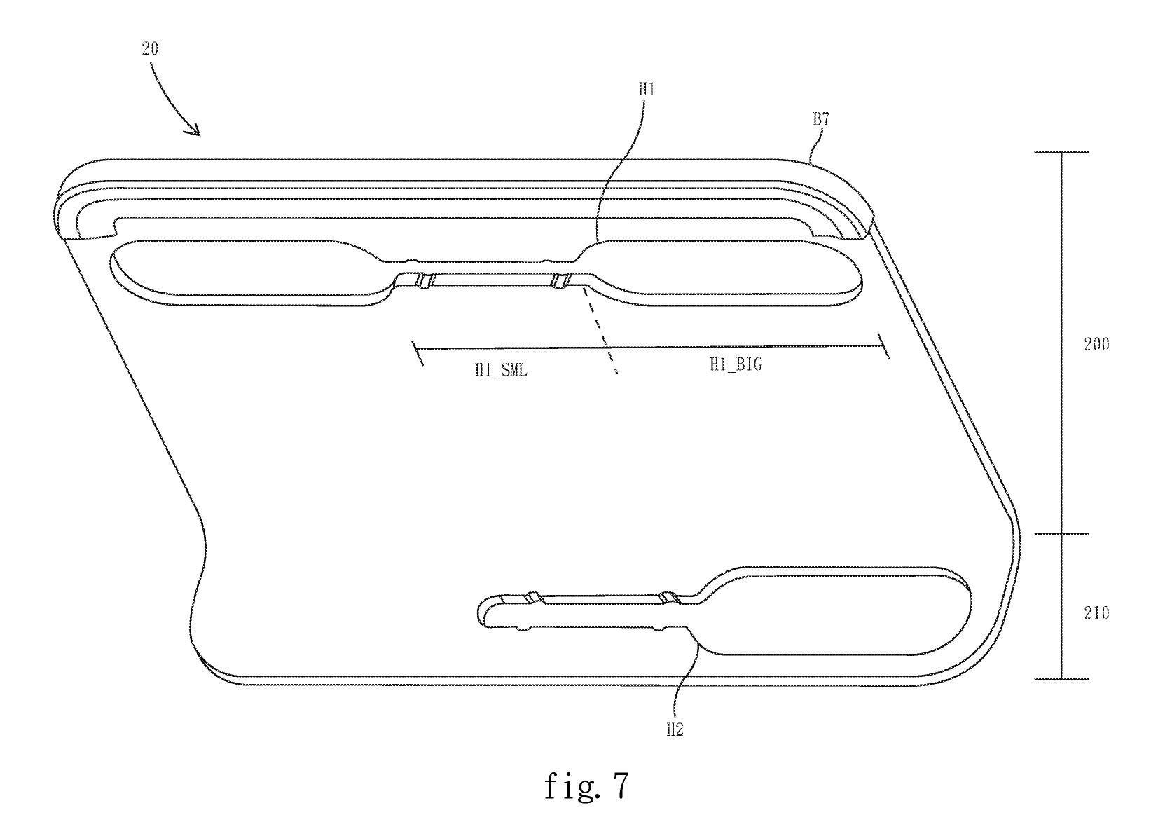

FIG. 7 is a perspective view of a support footing 20 according to an embodiment of the invention. The support footing 20 comprises mainly a pair of supporting plate 200 and 210 which form a bend. The supporting plate 200 and 210 each has an engaging hole H1 and H2. Engaging hole H1 consists of two big holes H1_BIG and a small hole H1_SML sandwiched therebetween. Engaging hole H2 consists of a big hole and a small hole connecting with each other, which are the same as big hole H1_BIG and a small hole H1_SML in shape and size. The support footing 20 includes in addition a rubber piece B7 to reduce friction.

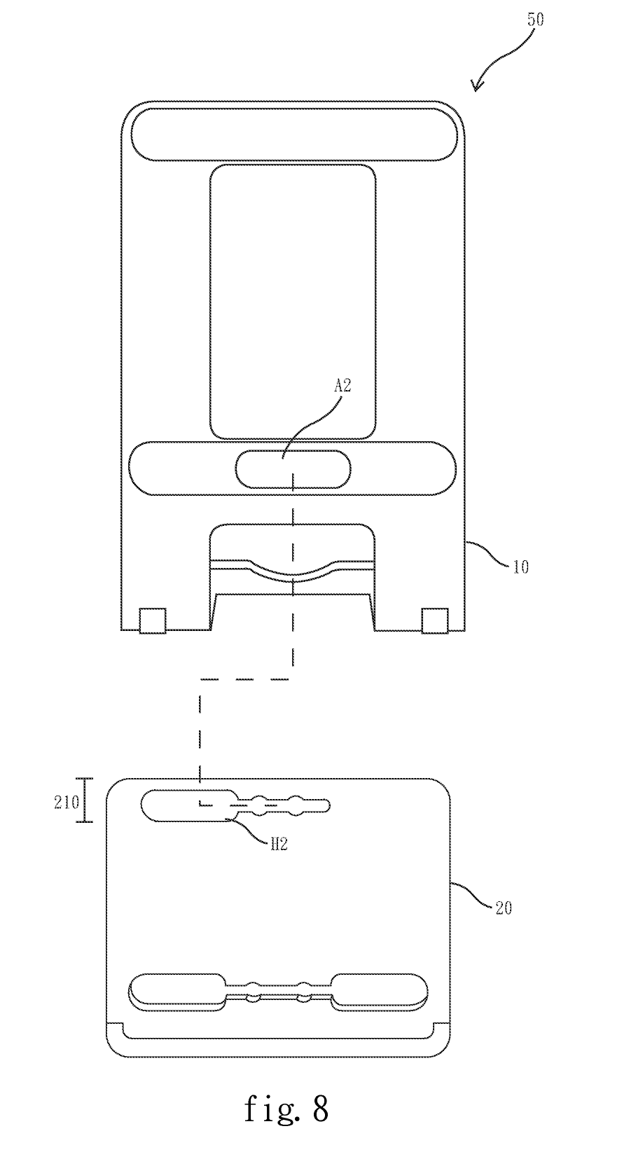

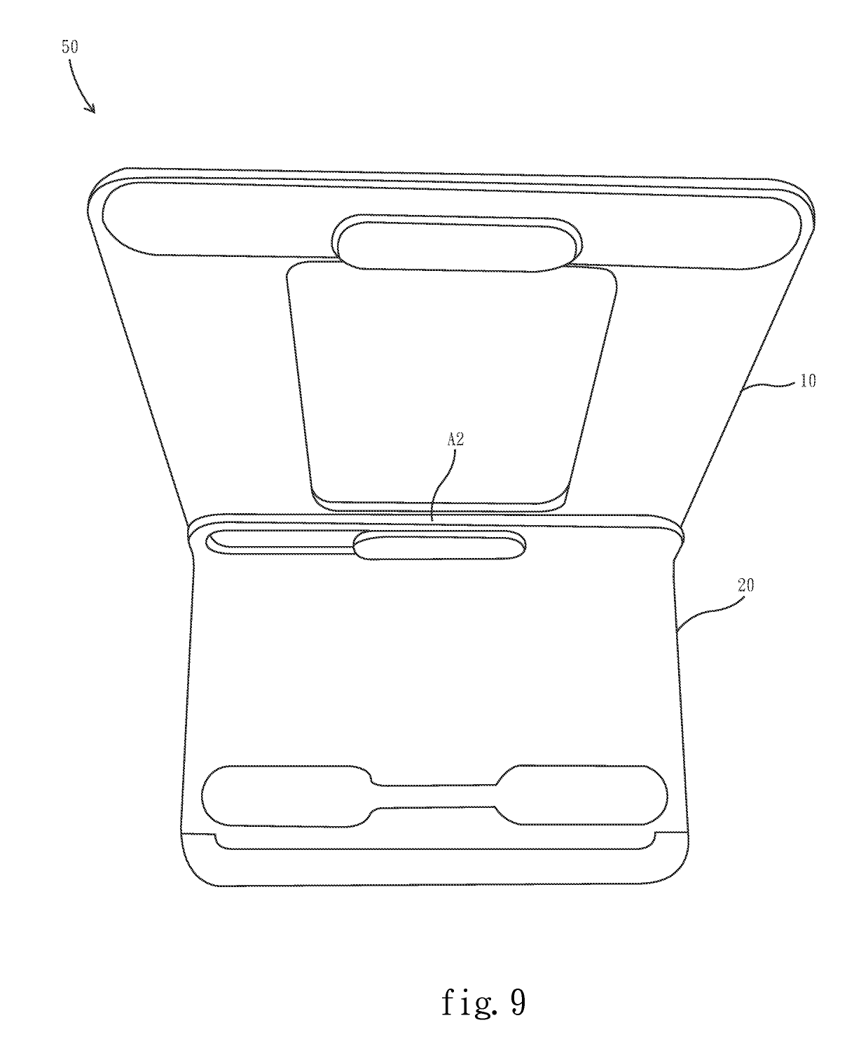

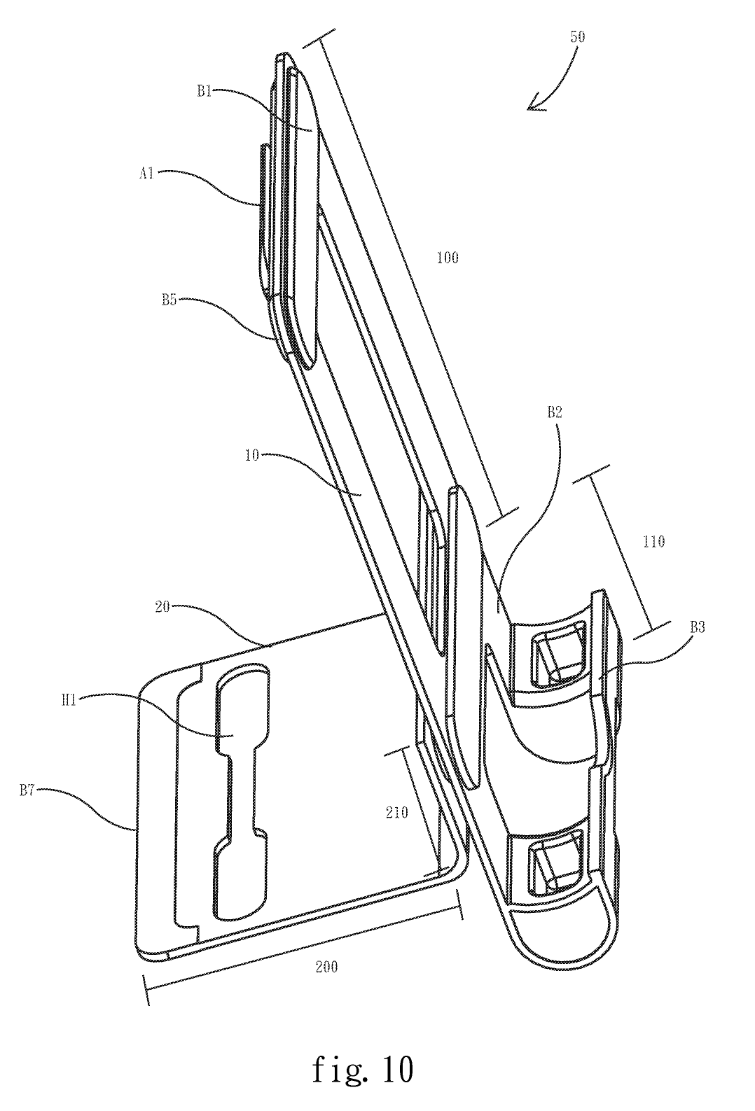

The support board 10 and the support footing 20 in an embodiment of the invention are assembled mainly by passing the head of any engaging member on the support plate 10 through any big hole on the support footing 20, and then coupling the neck with the small hole. Referring to FIG. 8 and FIG. 9, FIG. 8 is an exploded view of a tablet PC bracket 50 in a first embodiment of the invention, and FIG. 9 is a corresponding perspective view. In FIG. 8, the head of engaging member A2 of the support board 10 passes through the supporting plate 210 via the big hole of engaging hole H2 and then moves to the right to enable the coupling between the neck of engaging member A2 and the small hole of engaging hole H2. FIG. 10 is a side view of FIG. 9. As shown, when the supporting plate 210 is engaged with the engaging member A2 via the engaging hole H2 and the supporting plate 200 is not pressed close to the prop-up member 110, the tablet PC bracket 50 could stand on a desktop/ground surface through the support of the supporting plate 200 and prop-up member 110.

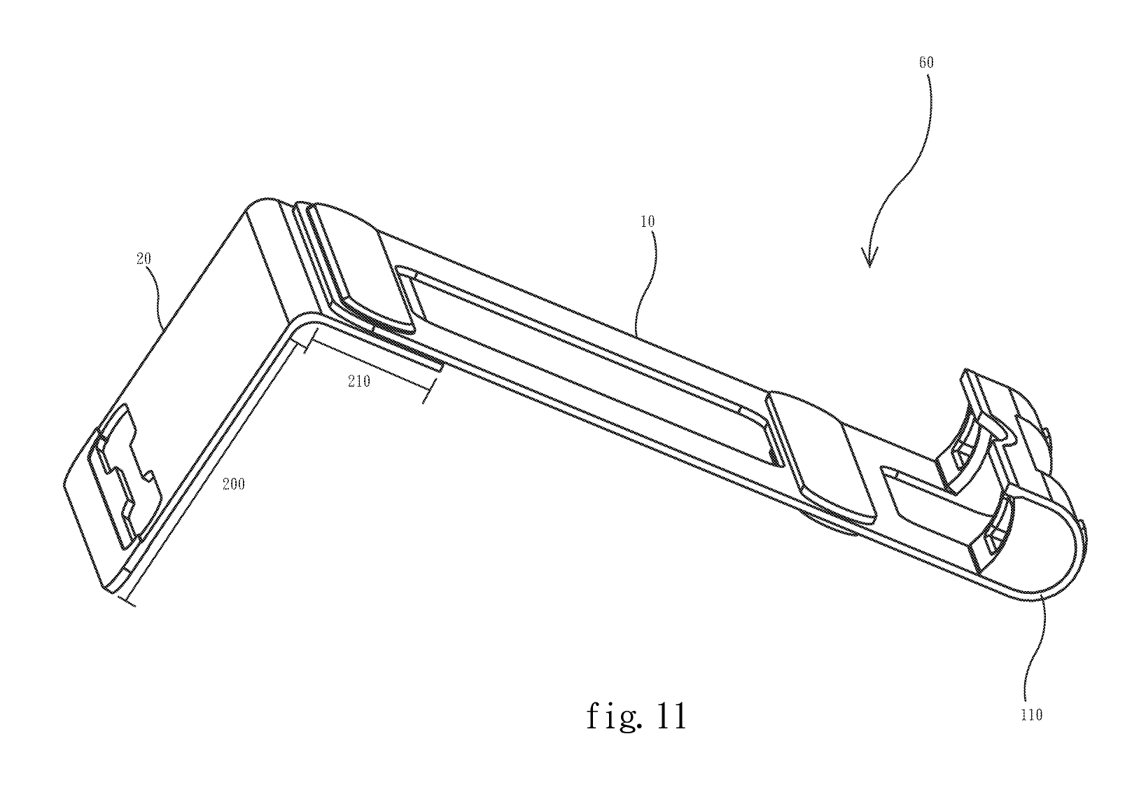

FIG. 11 is a perspective view of a tablet PC bracket 60 according to a second embodiment of the invention. The tablet PC bracket 60 is assembled in principle by coupling the supporting plate 210 to the engaging member A1. People with common knowledge in the field can easily understand the manner of assembly shown in FIG. 11 based on the descriptions given above. Thus the assembly method in the second embodiment will not be elaborated here.

Similarly, the supporting plate 200 can also be coupled to the engaging member A1 or A2 to enable the support bracket to achieve different support angles. In other words, when the supporting plate 200 is coupled to the engaging member A1 or A2 via the engaging hole Hl and the supporting plate 210 is not pressed close to the prop-up member 110, a different tablet PC bracket is assembled (not shown in the figures), which could stand on a desktop/ground surface through the support of the supporting plate 210 and the prop-up member 110.

As described above, the tablet PC bracket of the invention relies mainly on the contact with the prop-up member 110 and the support footing 20 with the desktop/ground surface for support. This way, it allows users to change the angle of support at will. Moreover, when the desktop/ground surface is uneven, such as an inclined surface or a step surface, users are still provided with an assembly option that offers stable support.

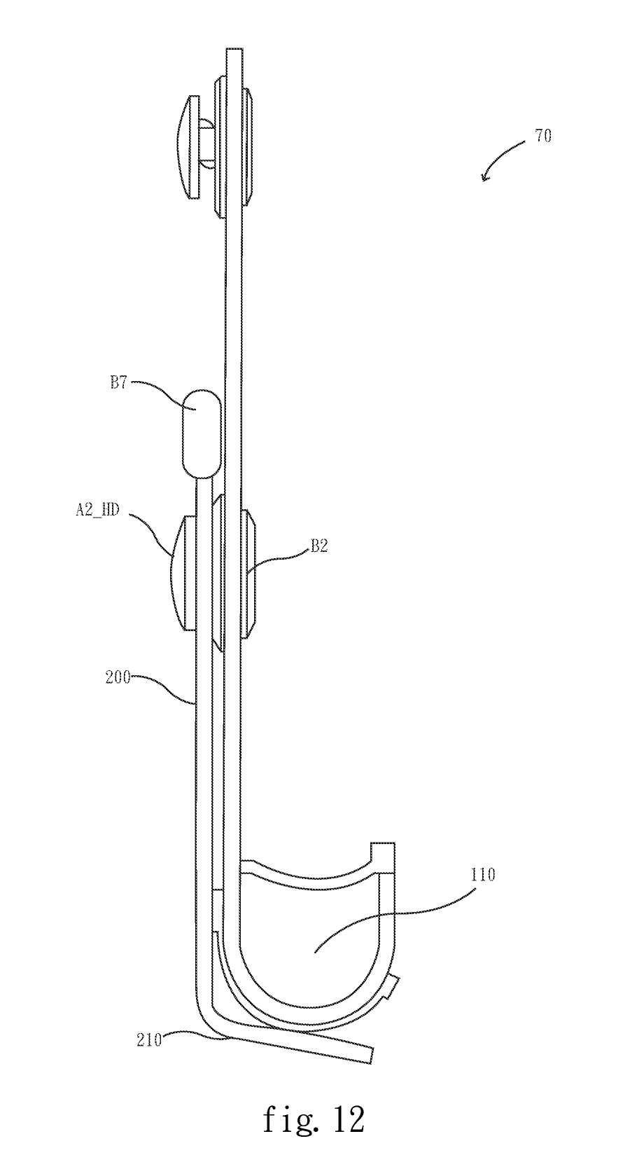

FIG. 12 is a side view of a tablet PC bracket 70 in folded state according to an embodiment of the invention. By adjusting the bend formed by the supporting plates 200 and 210, the supporting plate 210 could press close to the prop-up member 110 when the supporting plate 200 is engaged with the engaging member A2 via the engaging hole Hl such that only a small space is required for the storage of the support bracket.

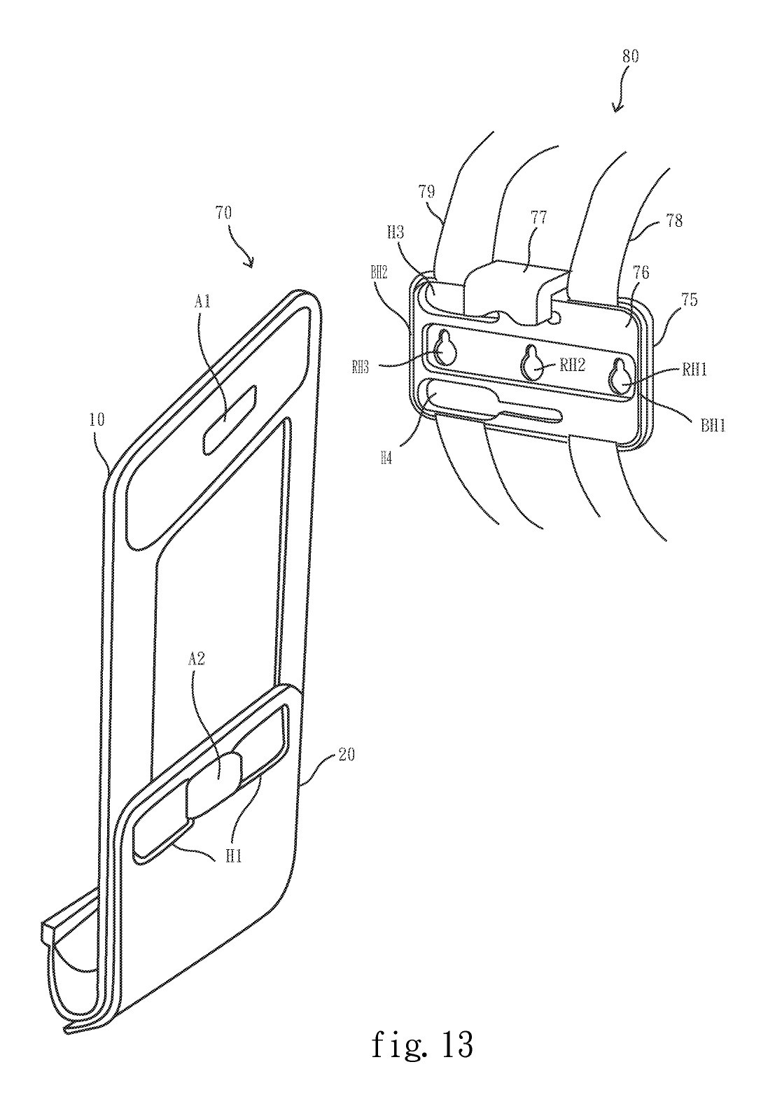

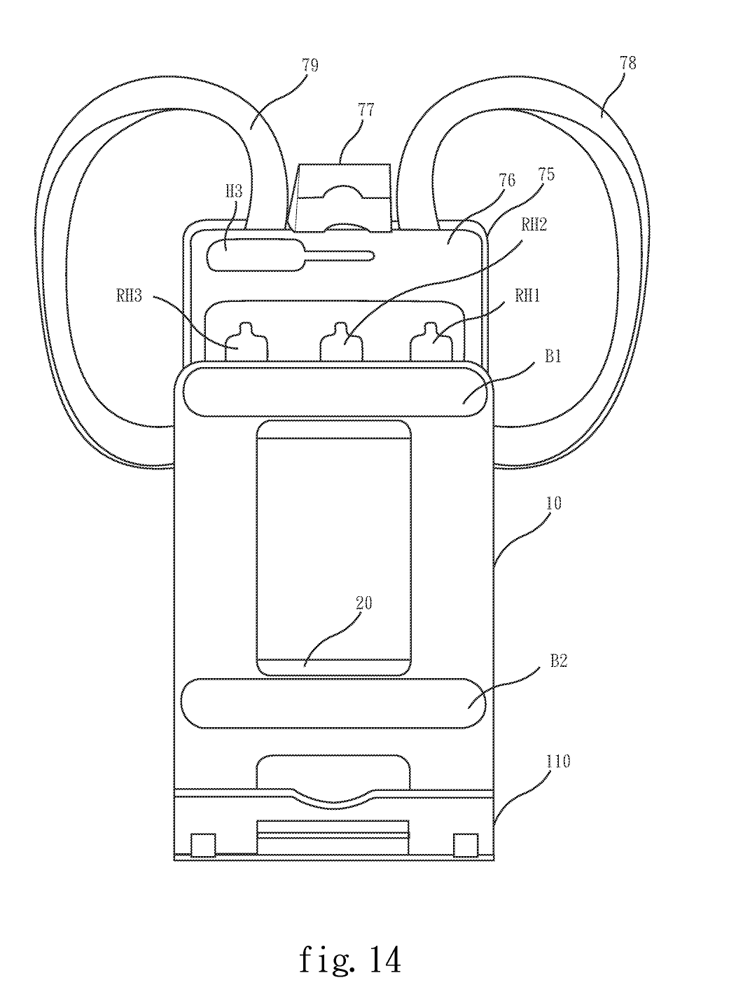

FIG. 13 is an exploded view of a mounted tablet PC bracket 80 according to a third embodiment of the invention. In this embodiment, the tablet PC bracket 80 comprises a tablet PC bracket 70 and a mounting kit 75. The mounting kit 75 consists of a body piece 76, a head piece 77 to prop against the top of table PC, and elastic bands 78, 79. The body piece 76 has engaging holes H3, H4, screw holes RH1-RH3, and bore holes BH1, BH2. The engaging holes H3, F4 are identical to the aforementioned engaging hole H2 of support footing 20 in shape and size such that they can couple with the engaging member A1 or A2 of tablet PC bracket 70. FIG. 13 shows the coupling between engaging hole F4 and engaging member A1. Under the circumstance, mounting kit 75 can achieve mounting in a number of manners. For example, the elastic bands 78, 79 can fasten respectively the body piece 76 as shown in FIG. 13, and by adjusting the length of the elastic bands 78, 79, the tablet PC bracket 80 can mount vertically on the headrest of an automobile. Users could also use an elastic band to fasten the body piece 76 via the bore holes BH1, BH2 and then tie the elastic band horizontally to the seat of an automobile to allow tablet PC bracket to mount vertically. Users also have the option to screw through screw holes RH1-RH3 to allow tablet PC bracket 80 to be mounted vertically on a wall surface. FIG. 14 is a perspective view of tablet PC bracket 80 (viewing from the front side of the support board 10 of tablet PC bracket 70). Moreover, when users use the mounting kit 75, it is not necessary for the support footing 20 to stay attached to the tablet PC bracket 80 that it can be removed to reduce the weight of the bracket. In addition, if engaging hole H3 is instead coupled to the engaging member Al in FIG. 13, the tablet PC can be placed horizontally due to the smaller space between the head piece 77 and the prop-up member 110. At this time, the head piece 77 and the prop-up member 110 are used to prop against each side of the table PC.

It should be noted that people with common knowledge in the field can produce many variations based on the possible needs of users. A few examples are cited below:

(1) The number, shape, size and thickness of rubber pieces may vary based on tablet PC's resistance to friction.

(2) The number and location of engaging members on the support board may vary based on the angle of support to be provided by the tablet PC bracket. The head of the engaging member may also come in different styles, as long as it can pass through the big hole on the support footing and will not allow the support board to be easily dislodged from the support footing. The neck of the engaging member can be a rolling ball structure or any other elastic structure that could aid the stability of engagement.

(3) The number of engaging holes on the support footing can also vary based on the angle of support to be provided by the tablet PC bracket. The key point is that each engaging hole must have at least a big hole and at least a small hole.

(4) The bend angle between the two supporting plates of the support footing may be adjusted according to the external shape of the prop-up member to achieve the purpose of space saving.

(5) The hollow-out pattern and style on the support board may be adjusted at will to allow better ventilation and cooling for the tablet PC.

As described above, the tablet PC bracket in the embodiments of the invention mainly use the different ways of assembly of a support board and a support footing to achieve different support angles or allow folding for easier storage and become useful in different environments. The tablet PC bracket can also provide support in mounted style using a support board and a mounting kit. The assembly of the support bracket according to the present invention does not require any tool and is easy. The support bracket can also be quickly dismantled, save space and is easy to carry.

The preferred embodiments of the present invention have been disclosed in the examples. However, all modifications and alterations without departing from the spirits of the invention shall remain within the protected scope and claims of the invention.

What is claimed is:

1. A tablet PC bracket for supporting a tablet PC, comprising:
a support board, consisting of:
a backboard for supporting the back of the tablet PC;
a prop-up member, arranged at the bottom of the front side of the backboard; and
a plurality of engaging members, each engaging member consisting of a head and a neck, one end of the neck being connected to the back of the backboard, and the other end of the neck being connected to the head; and
a support footing, consisting of:
a first supporting plate, having a first engaging hole; and
a second supporting plate, connecting to the first supporting plate such that the support footing forms a bend, the second supporting plate having a second engaging hole, where both the first engaging hole and the second engaging hole contain a big hole allowing any head of the plurality of engaging members to pass through the support footing and a small hole that could engage any neck of the plurality of engaging members;
wherein when the first supporting plate engages any one of the plurality of engaging members through the first engaging hole and the second supporting plate is not pressed close to the prop-up member, the tablet PC bracket could be braced through the second supporting plate and the prop-up member; when the second supporting plate engages any one of the plurality of engaging members through the second engaging hole and the first supporting plate is not pressed close to the prop-up member, the tablet PC bracket could be braced through the first supporting plate and the prop-up member.

2. The tablet PC bracket according to claim 1, wherein when the first supporting plate engages any of the plurality of engaging members through the first engaging hole, the second supporting plate is pressed close to the prop-up member through the bend.

3. The tablet PC bracket according to claim 2, further comprising a mounting kit for mounting the tablet PC bracket, wherein the mounting kit has a third engaging hole, the third engaging hole containing a big hole and a small hole.

4. The tablet PC bracket according to claim 3, wherein the mounting kit further consisting of a bore hole and an elastic band, the elastic band fastens the mounting kit through the bore hole.

5. The tablet PC bracket according to claim 3, wherein the mounting kit further includes a screw hole.

6. The tablet PC bracket according to claim 3, wherein the mounting kit further includes a head piece to prop against the top or side of the tablet PC.

7. The tablet PC bracket according to claim 1, further comprising a rubber pad engaging the prop-up member to raise the prop-up member for supporting other small-sized electronic devices.
